(19) United States
(12) Patent Application Publication
(10) Pub. No.: US 2006/0237782 A1
(43) Pub. Date: Oct. 26, 2006

(54) Power semiconductor device with L-shaped source region

(75) Inventors: Jun Zeng, Taipei Hsien (TW); Po-I Sun, Taipei Hsien (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: Pyramis Corporation

(21) Appl. No.: 11/194,353

(22) Filed: Aug. 1, 2005

(30) Foreign Application Priority Data
Apr. 21, 2005 (TW) 094112760

(51) Int. Cl. H01L 29/94

(52) U.S. Cl. 257/330; 257/331; 257/E29.201

(57) ABSTRACT

A power semiconductor device includes a substrate, a well region, a body region, a trench gate, a gate oxide layer, an L-shaped source region, an inter-layer dielectric layer and a metal layer. The body region is formed on the well region. The trench gate is formed at bilateral sides of the well region. The gate oxide layer is formed on sidewall and bottom of the trench gate. The L-shaped source region has a horizontal portion and a vertical portion formed on a portion of top region and bilateral sides of the body region, respectively. The inter-layer dielectric layer is formed on the trench gate and a portion of the L-shaped source region, thereby defining a contact window therein. The metal layer is formed on the inter-layer dielectric layer, the body region and the L-shaped source region, and connected to the L-shaped source region via the contact window.

### FIELD OF THE INVENTION

The present invention relates to a power semiconductor device, and more particularly to a power semiconductor device with an L-shaped source region.

### BACKGROUND OF THE INVENTION

Recently, power semiconductor devices such as power MOSFET (metal oxide semiconductor field effect transistor), IGBT (Insulated Gate Bipolar Transistor), JFET (Junction Field Effect Transistor) or Rectifier, have achieved a great deal of advance in their performance and manufacturing process technology. On of the major trends for further improving power device characteristics and reducing the manufacturing cost thereof is to employ the so-called trench-gated technology. By making use of the trench-gated technology, the cell pitch of the power device is shrunken and the device channel density can be increased significantly. As a consequence, an extremely low on-state power loss can be achieved with a low on-resistance or low forward voltage drop.

Unfortunately, increasing the channel density of a power device often results in degradation of the device safe operation area (SOA) and ruggedness thereof. In order to resolve this negative impact, the source region (e.g. N+ region for N channel) and the body region (e.g. P+ region for N channel) must be designed and implemented properly with a very precise fabrication process control. The idealized N+ source and P+body region combination should produce a P+body region/well (e.g. P region for N channel) having minimum resistance, as well as a very low common emitter current gain of the parasitic BJT formed by the N+ source region, P+body region/P well and N epitaxial layer. To achieve these characteristics, the N+ source region should be completely surrounded by the P+body region without increasing the threshold voltage of the device, and the P+body region should be deep enough without decreasing the breakdown voltage of device.

Please refer to FIGS. 1, 2 and 3, which illustrate three different trench-gated power semiconductor devices.

The trench-gated power semiconductor device of FIG. 1 comprises an N epitaxial substrate 11, a P well region 12, a P+ body region 13, a trench gate 14, a gate oxide layer 15, an N+ source region 16, an ILD (Inter-Layer Dielectrics) layer 17 and a metal layer 19. The P well region 12 is formed in the N epitaxial substrate 11. The P+ body region 13 is formed on the P well region 12. The trench gate 14 is formed at bilateral sides of the P well region 12. The gate oxide layer 15 is formed on sidewall and bottom of the trench gate 14. The N+ source region 16 is formed on bilateral sides of the P+ body region 13. The ILD layer 17 is formed on the trench gate 14 and a portion of the N+ source region 16, thereby defining a contact window 18 therein. The metal layer 19 is formed on the ILD layer 17, the P+ body region 13 and the N+source region 16. Via the contact window 18, the metal layer 19 is connected to the N+ source region 16. As can be seen in FIG. 1, the P+ body region 13 is made to be deeper than the N+ source region 16, and to be wide enough to surround the N+ source region 16 as much as possible.

The trench-gated power semiconductor device of FIG. 2 is similar to that of FIG. 1, except that the N+ source region 16 is formed on the P+ body region 13 and a portion of the P well region 12. In addition, the trench-gated power semiconductor device of FIG. 3 is also similar to that of FIG. 1, except that the N+ source region 16 is formed on bilateral sides of the P+ body region 13 and a portion of the P well region 12. Likewise, as shown in FIGS. 2 and 3, the P+ body region 13 is made to be deeper than the N+ source region 16, and to be wide enough to surround the N+ source region 16 as much as possible.

The resulting structures of the N+ source region 16 and the P well region 12 for these three trench-gated power semiconductor devices are fabricated according to the current trench-gated technology. However, there still exist at least two drawbacks in these prior arts. First, since the P+ body region 13 is deeper than the N+ source region 16, the channel region is exposed to the P+ body region 13. Under this circumstance, the dopant of P+ region may easily get into the channel, thereby causing a higher and uncontrollable threshold voltage. Secondly, the deep P+ body region 13 limits the depletion region spreading inside the P well region 13. Consequently, as the depth of the P+ body region 13 is increased, the breakdown voltage of the device will be limited or even be reduced.

In views of the above-described disadvantages resulted from the prior art, the applicant keeps on carving unflaggingly to develop a power semiconductor device with an L-shaped source region according to the present invention through wholehearted experience and research.

### SUMMARY OF THE INVENTION

An object of the present invention is to provide a power semiconductor device with an L-shaped source region to minimize the negative impact of the P+ body region on the threshold voltage and increase the breakdown voltage of the power semiconductor device.

Another object of the present invention is to provide a power semiconductor device with an L-shaped source region so as to significantly shrink cell pitch and increase the device channel density without impairing the electrical characteristics thereof.

In accordance with a first aspect of the present invention, there is provided a power semiconductor device with an L-shaped source region. The power semiconductor device comprises a substrate, a well region, a body region, a trench gate, a gate oxide layer, an L-shaped source region, an inter-layer dielectric layer and a metal layer. The well region is formed in the substrate. The body region is formed on the well region. The trench gate is formed at bilateral sides of the well region. The gate oxide layer is formed on sidewall and bottom of the trench gate. The L-shaped source region has a horizontal portion and a vertical portion formed on a portion of top region and bilateral sides of the body region, respectively. The inter-layer dielectric layer is formed on the trench gate and a portion of the L-shaped source region, thereby defining a contact window therein. The metal layer is formed on the inter-layer dielectric layer, the body region and the L-shaped source region, and connected to the L-shaped source region via the contact window.

Preferably, the power semiconductor device is a power MOSFET (metal oxide semiconductor field effect transistor).

Preferably, the substrate is an N epitaxial substrate.

Preferably, the gate oxide layer is a thermal oxide layer.

Preferably, the trench gate is made of polysilicon.

In an embodiment, the well region is a P well region.

In an embodiment, the body region is a P+ body region.

In an embodiment, the L-shaped source region is N+ doped.

Preferably, the inter-layer dielectric layer is a deposition oxide layer.

Preferably, the depth of the vertical portion of the L-shaped source region is equal to or larger than that of the body region.

In accordance with a second aspect of the present invention, there is provided a power semiconductor device with an L-shaped source region. The power semiconductor device comprises a drain region, a body region, a trench gate, a gate oxide layer, an L-shaped source region, an inter-layer dielectric layer and a metal layer. The body region is formed on the drain region. The trench gate is formed at bilateral sides of the body region. The gate oxide layer is formed on sidewall and bottom of the trench gate. The L-shaped source region has a horizontal portion and a vertical portion formed on a portion of top region and bilateral sides of the body region, respectively. The inter-layer dielectric layer is formed on the trench gate. The metal layer is formed on the inter-layer dielectric layer, the body region and the L-shaped source region, and connected to the L-shaped source region.

Preferably, the inter-layer dielectric layer is a BPSG deposition oxide layer.

Preferably, the drain region includes an N epitaxial layer.

In an embodiment, the body region includes a P well region and a P+ doping layer.

Preferably, the depth of the vertical portion of the L-shaped source region is equal to or larger than that of the P+ doping layer.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-section view illustrating a conventional trench-gated power semiconductor device;

FIG. 2 is a schematic cross-section view illustrating another conventional trench-gated power semiconductor device;

FIG. 3 is a schematic cross-section view illustrating another conventional trench-gated power semiconductor device;

FIG. 4 is a schematic cross-sectional view illustrating a power semiconductor device with an L-shaped source region according to a preferred embodiment of the present invention;

FIGS. 5(A)^{˜} 5(C) illustrate a process for fabricating the power semiconductor device of FIG. 4; and

FIG. 6 is a schematic cross-sectional view illustrating a power semiconductor device with an L-shaped source region according to another preferred embodiment of the present invention.

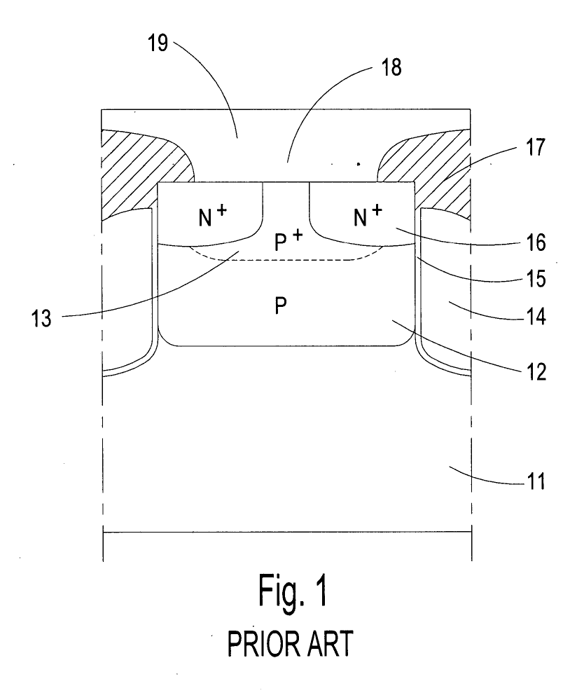

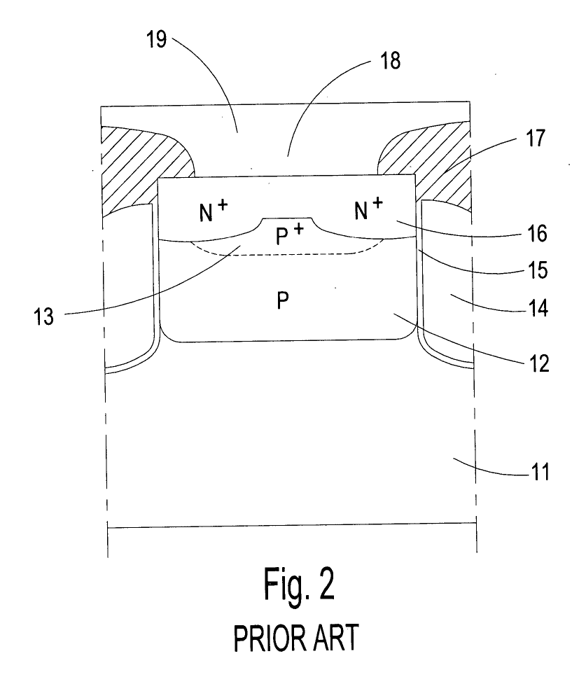

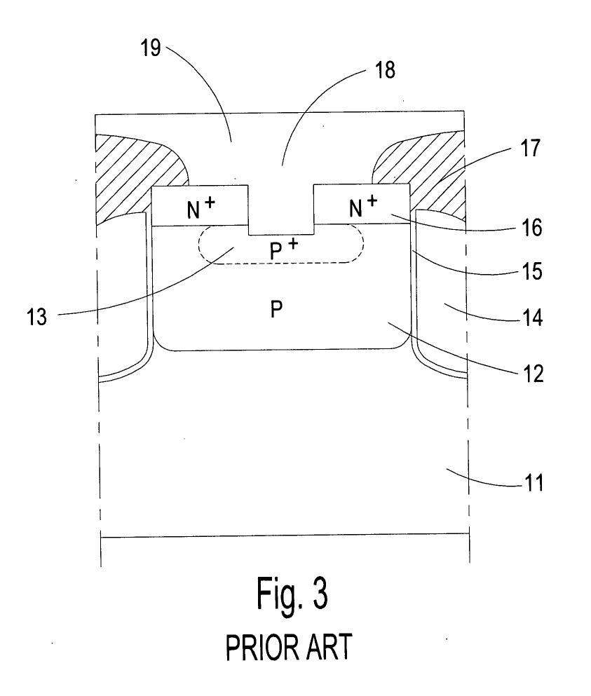

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

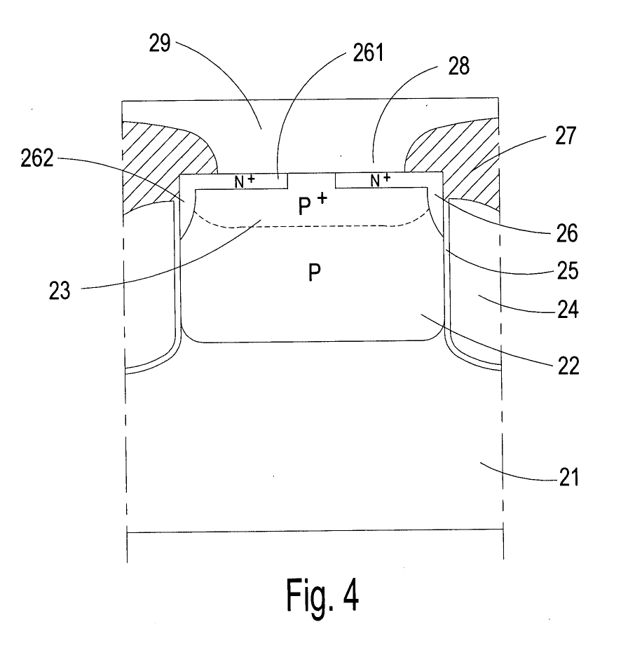

Referring to FIG. 4, a schematic cross-sectional view of a power semiconductor device with an L-shaped source region according to a preferred embodiment of the present invention is illustrated. The trench-gated power semiconductor device of FIG. 4 comprises a substrate 21, a well region 22, a body region 23, a trench gate 24, a gate oxide layer 25, an L-shaped source region 26, an ILD (Inter-Layer Dielectrics) layer 27 and a metal layer 29. The well region 22 is formed in the substrate 21. The body region 23 is formed on the well region 22. The trench gate 24 is formed at bilateral sides of the well region 22. The gate oxide layer 25 is formed on sidewall and bottom of the trench gate 24. The L-shaped source region 26 has a horizontal portion 261 and a vertical portion 262 respectively formed on a portion of top region and bilateral sides of the body region 23. The ILD layer 27 is formed above the trench gate 24 and a portion of the L-shaped source region 26, thereby defining a contact window 28 therein. The metal layer 29 is formed on the ILD layer 27, the body region 23 and the L-shaped source region 26. Via the contact window 28, the metal layer 29 is connected to the L-shaped source region 26.

An exemplary power semiconductor device described in the above embodiment is a power MOSFET. In application, the substrate 21 is an N epitaxial substrate serving as a drain region. The trench gate 24 is preferably made of polysilicon. The gate oxide layer 25 is a thermal oxide layer formed according to a thermal oxidation procedure. In addition, the well region 22 and the body region 23 are P well region and P+ body region, respectively. The L-shaped source region 26 is N+ doped.

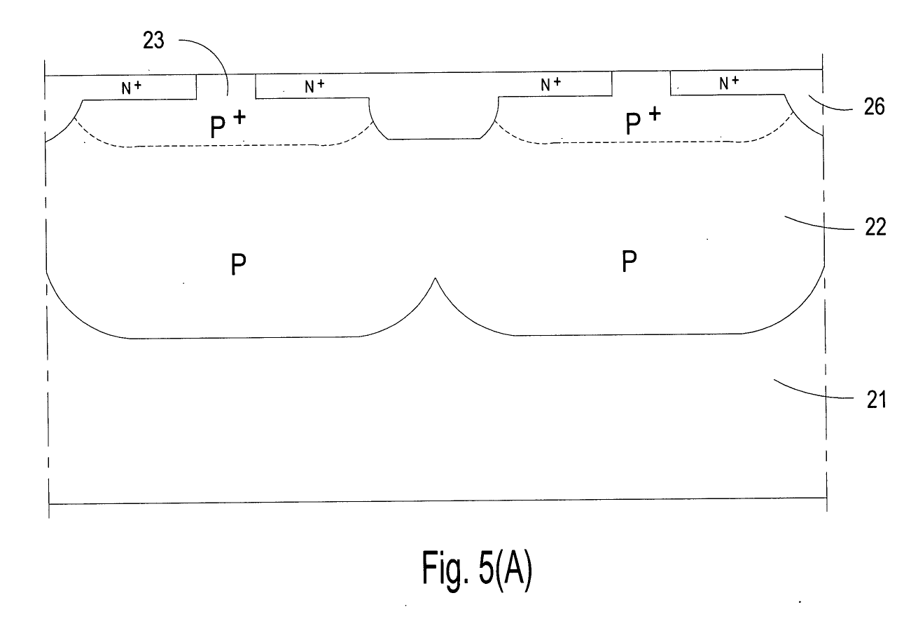

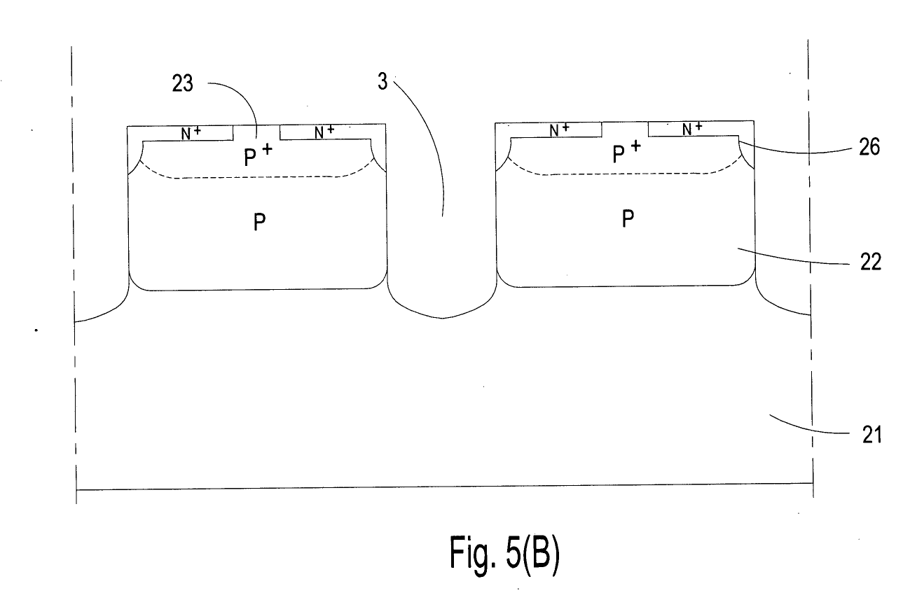

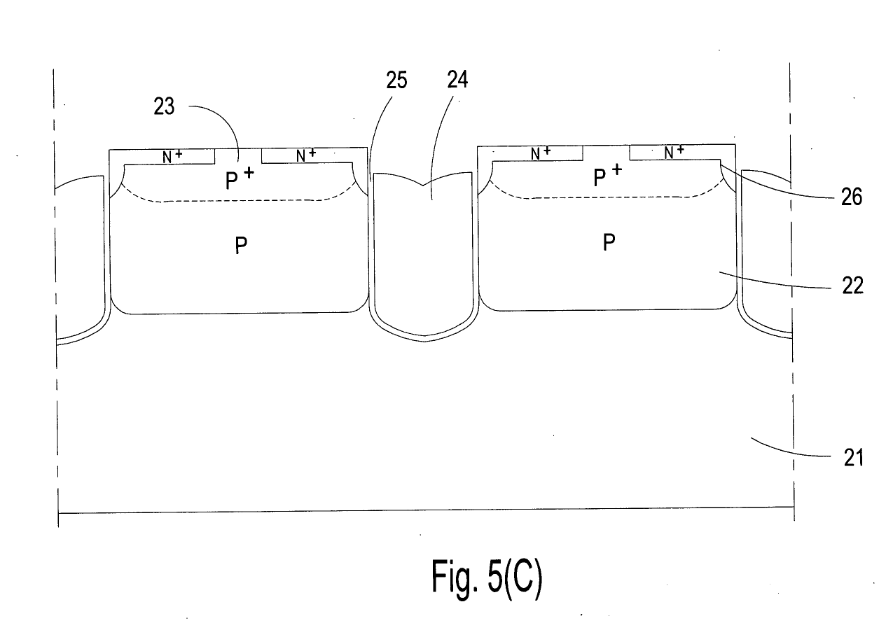

A process for fabricating the power semiconductor device as shown in the above embodiment will be illustrated with reference to FIGS. 5(A)^{˜} (C). First of all, as shown in FIG. 5(A), an EPI/substrate 21 is provided. Successively, P type, P+ type and N+ type doping procedures are carried out, thereby forming the well region 22, the body region 23 and the L-shaped source region 26 as shown in FIG. 5(A). Then, by making use of photolithography and etch process, a trench structure 3 as shown in FIG. 5(B) is defined. Successively, a thermal oxidation procedure is performed to form a thermal oxide layer 25 on sidewall of the trench structure 3, a polysilicon layer is filled in the trench structure 3, and an etch back procedure is performed, thereby forming the trench gate 24 as shown in FIG. 5(C). Afterwards, a BPSG oxide layer is deposited on the resulting structure of FIG. 5(C) to form the ILD layer 27 as shown in FIG. 4. Then, by a photolithography and etch procedure, a portion of the ILD layer 27 is removed so as to define a contact window 28. Finally, a metal layer 29 is formed on the ILD layer 27 to connect with the L-shaped source region 26 via the contact window 28. Meanwhile, the power semiconductor device with an L-shaped source region is produced.

It is noted that, however, those skilled in the art will readily observe that numerous modifications and alterations of the structure and the fabricating process may be made while retaining the teachings of the invention. Accordingly, the above disclosure should be limited only by the bounds of the following claims.

Please refer to FIG. 4 again. The depth of the vertical portion 262 of the L-shaped source region 26 is equal to or slightly larger than that of the body region 23. As a consequence, the negative impact of the P+ body region on the threshold voltage is minimized and the breakdown voltage of the power semiconductor device is increased. Furthermore, the cell pitch of the power semiconductor device is shrunken and the channel density of the power semiconductor device is significantly increased without impairing the electrical characteristics thereof.

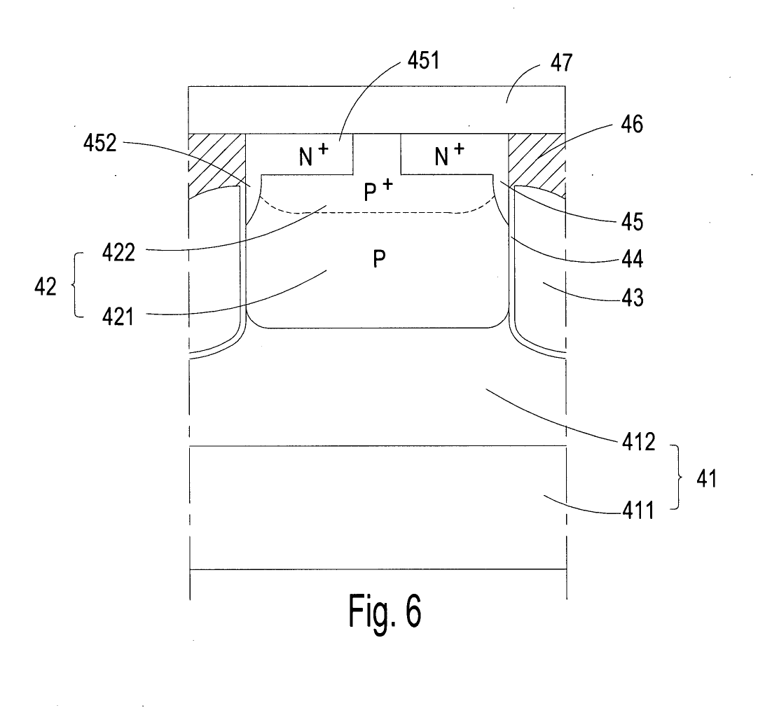

A further embodiment of a power semiconductor device with an L-shaped source region is illustrated in FIG. 6. In this embodiment, the power semiconductor device comprises a drain region 41, a body region 42, a trench gate 43, a gate oxide layer 44, an L-shaped source region 45, an ILD (Inter-Layer Dielectrics) layer 46 and a metal layer 47. The body region 42 is formed on the drain region 41. The trench gate 43 is formed at bilateral sides of the body region 42. The gate oxide layer 44 is formed on sidewall and bottom of the trench gate 43. The L-shaped source region 45 has a horizontal portion 451 and a vertical portion 452 respectively formed on a portion of top region and bilateral sides of the body region 42. The ILD layer 46 is formed above the trench gate 43. After the metal layer 47 is formed on the ILD layer 46, the body region 42 and the L-shaped source region 45, the power semiconductor device with an L-shaped source region is produced.

An exemplary power semiconductor device described in the above embodiment is a power MOSFET. In application, an exemplary ILD layer 46 is BPSG oxide layer. The L-shaped source region 45 is N+ doped. The drain region 41 includes an N+substrate 411 and an N epitaxial layer 412. The body region 42 includes a P well region 421 and a P+ doping layer 422. Likewise, the depth of the vertical portion 452 of the L-shaped source region 45 is equal to or slightly larger than that of the P+ doping layer 422. As a consequence, the cell pitch of the power semiconductor device is shrunken and the device channel density is significantly increased without impairing the electrical characteristics thereof.

From the above description, the power semiconductor device with an L-shaped source region of the invention can be applied to many power semiconductor devices such as power MOSFET (metal oxide semiconductor field effect transistor). With the L-shaped source region, the negative impact of the P+ body region on the threshold voltage is minimized and the breakdown voltage of the power semiconductor device is increased. Furthermore, the cell pitch of the power semiconductor device is shrunken and the channel density of the power semiconductor device is significantly increased without impairing the electrical characteristics thereof.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power semiconductor device with an L-shaped source region, comprising:
a substrate;
a well region formed in said substrate;
a body region formed on said well region;
a trench gate formed at bilateral sides of said well region;
a gate oxide layer formed on sidewall and bottom of said trench gate;
an L-shaped source region having a horizontal portion and a vertical portion formed on a portion of top region and bilateral sides of said body region, respectively;
an inter-layer dielectric layer formed on said trench gate and a portion of said L-shaped source region, thereby defining a contact window therein; and
a metal layer formed on said inter-layer dielectric layer, said body region and said L-shaped source region, and connected to said L-shaped source region via said contact window.

2. The power semiconductor device according to claim 1 wherein said power semiconductor device is a power MOSFET (metal oxide semiconductor field effect transistor).

3. The power semiconductor device according to claim 1 wherein said substrate is an N epitaxial substrate.

4. The power semiconductor device according to claim 1 wherein said gate oxide layer is a thermal oxide layer.

5. The power semiconductor device according to claim 1 wherein said trench gate is made of polysilicon.

6. The power semiconductor device according to claim 1 wherein said well region is a P well region.

7. The power semiconductor device according to claim 1 wherein said body region is a P+ body region.

8. The power semiconductor device according to claim 1 wherein said L-shaped source region is N+ doped.

9. The power semiconductor device according to claim 1 wherein said inter-layer dielectric layer is a deposition oxide layer.

10. The power semiconductor device according to claim 1 wherein the depth of said vertical portion of said L-shaped source region is equal to or larger than that of said body region.

11. A power semiconductor device with an L-shaped source region, comprising:
a drain region;
a body region formed on said drain region;
a trench gate formed at bilateral sides of said body region;
a gate oxide layer formed on sidewall and bottom of said trench gate;
an L-shaped source region having a horizontal portion and a vertical portion formed on a portion of top region and bilateral sides of said body region, respectively;
an inter-layer dielectric layer formed on said trench gate; and
a metal layer formed on said inter-layer dielectric layer, said body region and said L-shaped source region, and connected to said L-shaped source region.

12. The power semiconductor device according to claim 11 wherein said inter-layer dielectric layer is a BPSG deposition oxide layer.

13. The power semiconductor device according to claim 11 wherein said power semiconductor device is a power MOSFET (metal oxide semiconductor field effect transistor).

14. The power semiconductor device according to claim 11 wherein said drain region comprises an N epitaxial layer.

15. The power semiconductor device according to claim 11 wherein said gate oxide layer is a thermal oxide layer.

16. The power semiconductor device according to claim 11 wherein said trench gate is made of polysilicon.

17. The power semiconductor device according to claim 11 wherein said body region comprises a P well region and a P+ doping layer.

18. The power semiconductor device according to claim 11 wherein the depth of said vertical portion of said L-shaped source region is equal to or larger than that of said P+ doping layer.

19. The power semiconductor device according to claim 11 wherein said L-shaped source region is N+ doped.
